(19) United States
(12) Patent Application Publication
(10) Pub. No.: US 2026/0304812 A1
(43) Pub. Date: Oct. 1, 2026

(54) METHOD FOR FABRICATING POWER SEMICONDUCTOR DEVICE AND POWER SEMICONDUCTOR DEVICE

(71) Applicant: Xiinergy Systems, Inc, PORT COQUITLAM (CA)

(72) Inventors: Ning Ze ZHUO, PORT COQUITLAM (CA); Yue FU, PORT COQUITLAM (CA); Ling Tao KONG, PORT COQUITLAM (CA)

(73) Assignee: Xiinergy Systems, Inc, PORT COQUITLAM (CA)

(21) Appl. No.: 19/262,023

(22) Filed: Jul. 7, 2025

(30) Foreign Application Priority Data
Mar. 31, 2025 (CN) 202510386284.0

(51) Int. Cl. H10D 30/01; H01L 21/265; H10D 30/66

(52) U.S. Cl. CPC H10D 30/0297; H10D 30/668; H10P 30/204; H10P 30/21

(57) ABSTRACT

A method for fabricating a power semiconductor device is provided, comprising: etching a substrate layer to form a first MESA region, a second MESA region, and a first trench; performing ion implantation at a bottom of the first trench, and activating implanted ions to form a doped ring on a side of the substrate layer close to the bottom of the first trench; forming a non-doped polysilicon layer at the bottom of the first trench, and performing ion implantation on the non-doped polysilicon layer to form a doped polysilicon layer; forming a source oxide layer, a source polysilicon layer, a gate oxide layer, and a gate polysilicon layer on a surface of the doped polysilicon layer in the first trench; and forming a source and a drain in the first MESA region and the second MESA region.

### RELATED APPLICATIONS

This application claims the benefit of priority to the Chinese Application No. 202510386284.0, filed on Mar. 31, 2025, and entitled “METHOD FOR FABRICATING POWER SEMICONDUCTOR DEVICE AND POWER SEMICONDUCTOR DEVICE”, the entire content of which is incorporated herein by reference in its entirety.

### TECHNICAL FIELD

The present invention relates to the technical field of semiconductor devices, and particularly to a method for fabricating a power semiconductor device and a power semiconductor device.

### BACKGROUND

The thermal oxidation process of semiconductors is an important process for forming a silicon dioxide (SiO₂) thin film on a silicon substrate during the fabrication of semiconductor devices. This process involves exposing the silicon substrate to a high-temperature atmosphere of oxygen or steam, usually conducted at temperatures above 800° C.

The difference in thermal oxidation rates is mainly caused by the influence of crystal orientation, resulting in variations in oxide layer thickness across different regions; in power semiconductor devices, during reverse voltage resistance, regions with thinner oxide layers are more prone to breakdown first, which reduces the voltage resistance capability of the device and limits the voltage resistance performance of the device. The high electric field causes the thinner oxide layer regions to generate more heat, gradually degrading the performance of the oxide layer, and may even lead to structural changes in the oxide layer, further affecting the performance and reliability of the device.

To sum up, in the existing technology, when using a thermal oxidation process to fabricate power semiconductor devices, there is a problem that the thickness of the deposited oxide layer is uneven at different positions of the substrate trench, thereby affecting the performance and reliability of the power semiconductor device.

### SUMMARY

To this end, the technical problem to be solved by the present invention is to overcome the problem that, when using thermal oxidation to fabricate power semiconductor devices, the thickness of the oxide layer formed by oxidation is uneven at different positions of the substrate trench, thereby affecting the performance and reliability of the power semiconductor device.

To solve the above technical problem, the present invention provides a method for fabricating a power semiconductor device, comprising: etching a substrate layer to form a first MESA region, a second MESA region, and a first trench; performing ion implantation at a bottom of the first trench, and activating implanted ions to form a doped ring in the substrate layer close to the bottom of the first trench; forming an undoped polysilicon layer at the bottom of the first trench, and performing ion implantation on the undoped polysilicon layer to form a doped polysilicon layer; forming a source oxide layer, a source polysilicon layer, a gate oxide layer, and a gate polysilicon layer on a surface of the doped polysilicon layer in the first trench; and forming a source and a drain respectively in the first MESA region and the second MESA region.

The present invention also provides a power semiconductor device, where the power semiconductor device is fabricated by a method comprising the following steps: etching a substrate layer to form a first MESA region, a second MESA region, and a first trench; performing ion implantation at a bottom of the first trench, and activating implanted ions to form a doped ring in the substrate layer close to the bottom of the first trench; forming an undoped polysilicon layer at the bottom of the first trench, and performing ion implantation on the undoped polysilicon layer to form a doped polysilicon layer; forming a source oxide layer, a source polysilicon layer, a gate oxide layer, and a gate polysilicon layer on a surface of the doped polysilicon layer in the first trench; and forming a source and a drain respectively in the first MESA region and the second MESA region.

By performing ion implantation at the bottom of the first trench to form a doped ring, and simultaneously depositing a non-doped polysilicon layer in the first trench and performing ion implantation on the non-doped polysilicon layer to form a doped polysilicon layer, since the oxidation rate of doped polysilicon is higher than that of monocrystalline silicon, the present application utilizes the synergistic effect of the doped ring and the doped polysilicon layer at the bottom of the first trench to increase the oxidation rate at the bottom of the first trench, thereby increasing the thickness of the oxide layer at the bottom of the first trench. In addition, the doped polysilicon layer is used as a buffer layer to cover the bottom of the first trench, filling in the microscopic unevenness at the bottom of the first trench, reducing the inconsistency of oxidation rates at different positions caused by differences in the deposition surface morphology. Moreover, certain stress is introduced during the deposition and ion implantation of the polysilicon layer, thereby affecting the lattice structure at the bottom of the first trench, changing the atomic spacing and chemical bond energy of different crystal planes, making the reaction activity of different crystal planes in the oxidation process more similar, and reducing the oxidation rate differences at different positions. As a result, the uniformity of the oxide layer thickness deposited at the bottom of the first trench is optimized, the problem of thin oxide layers at the bottom and corners of the first trench is solved, thereby improving the insulation performance of the device and effectively avoiding the problem of low-voltage breakdown of the device caused by locally thin oxide layers.

Moreover, by performing ion implantation at the bottom of the first trench and the non-doped polysilicon layer, with different combinations of donor or acceptor impurities and implantation doses, the device's Miller capacitance and characteristic on-resistance can be effectively reduced, and the breakdown voltage of the device can be increased, thereby achieving regulation of the device's performance.

### BRIEF DESCRIPTION OF THE DRAWINGS

In order to make the content of the present invention more easily understood, the following provides a further detailed description of the present invention with reference to the specific exemplary embodiments of the invention and the accompanying drawings.

FIG. 1 is a flowchart of a method for fabricating a power semiconductor device according to the present disclosure.

FIG. 2A to FIG. 2E illustrate a process of forming a doping ring according to the present disclosure. FIG. 2A is a schematic diagram of forming a hard mask on the substrate layer. FIG. 2B is a schematic diagram of etching the substrate layer. FIG. 2C is a schematic diagram of forming a first ion implantation window in FIG. 2B. FIG. 2D is a schematic diagram of performing ion implantation at the bottom of a first trench. FIG. 2E is a schematic diagram of forming a doping ring in the substrate layer.

FIG. 3A to FIG. 3D illustrate a process of forming a non-doped polysilicon layer according to the present disclosure. FIG. 3A is a schematic diagram of filling non-doped polysilicon in a first trench. FIG. 3B is a schematic diagram of forming a non-doped polysilicon layer at the bottom of the first trench. FIG. 3C is a schematic diagram of forming a second ion implantation window in FIG. 3B. FIG. 3D is a schematic diagram of performing ion implantation on the non-doped polysilicon layer.

FIG. 4A to FIG. 4C illustrate a process of forming a source polysilicon and an oxide layer according to the present disclosure. FIG. 4A is a schematic diagram of forming a field oxide layer in a first trench. FIG. 4B is a schematic diagram of a first type of source polysilicon layer and source oxide layer. FIG. 4C is a schematic diagram of a second type of source polysilicon layer and source oxide layer.

FIG. 5A to FIG. 5B illustrate a process of forming a first type of gate polysilicon and an oxide layer according to the present disclosure. FIG. 5A is a schematic diagram of forming an isolation oxide layer. FIG. 5B is a schematic diagram of forming a gate oxide layer and a gate polysilicon layer.

FIG. 6 is a flowchart of a process of forming a gate polysilicon and an oxide layer according to the present disclosure.

FIG. 7A to FIG. 7D illustrate a process of forming a source and a drain according to the present disclosure. FIG. 7A is a schematic diagram of forming a body region and a source region in a first MESA region and a second MESA region. FIG. 7B is a schematic diagram of contact hole etching. FIG. 7C is a schematic diagram of ion implantation activation and filling of the contact holes. FIG. 7D is a schematic diagram of metal layer deposition.

FIG. 8A to FIG. 8D illustrate a process of forming a source and a drain according to the present disclosure. FIG. 8A is a schematic diagram of forming a body region and a source region in a first MESA region and a second MESA region. FIG. 8B is a schematic diagram of contact hole etching. FIG. 8C is a schematic diagram of ion implantation activation and filling of the contact holes. FIG. 8D is a schematic diagram of metal layer deposition.

FIG. 9A to FIG. 9B illustrate the structure of a conventional power semiconductor device and a power semiconductor device provided in the present disclosure. FIG. 9A is a schematic structural diagram of a conventional power semiconductor device. FIG. 9B is a schematic structural diagram of a power semiconductor device provided in present disclosure.

Description of reference numerals in the drawings: 11, substrate layer; 111, first MESA region; 112, second MESA region; 113, first trench; 114, doped ring; 12, hard mask; 13, first ion implantation blocking layer; 131, second trench; 132, first ion implantation window; 14, non-doped polysilicon; 141, non-doped polysilicon layer; 142, doped polysilicon layer; 15, second ion implantation blocking layer; 151, third trench; 152, second ion implantation window; 16, field oxide layer; 161, fourth trench; 162, source oxide layer; 17, source polysilicon layer; 18, fifth trench; 19, isolation oxide layer; 20, first gate oxide layer; 21, first gate polysilicon layer; 22, second gate oxide layer; 23, third gate oxide layer; 24, second gate polysilicon layer; 25, fourth gate oxide layer; 26, body region; 27, source region; 28, oxide layer; 29, first contact hole; 30, second contact hole; 31, tungsten plug; 32, metal layer.

### DETAILED DESCRIPTION

The following provides a further description of the present invention in conjunction with the accompanying drawings and specific exemplary embodiments, so that a person skilled in the art can better understand and implement the present invention, but the cited embodiments are not intended to limit the present invention.

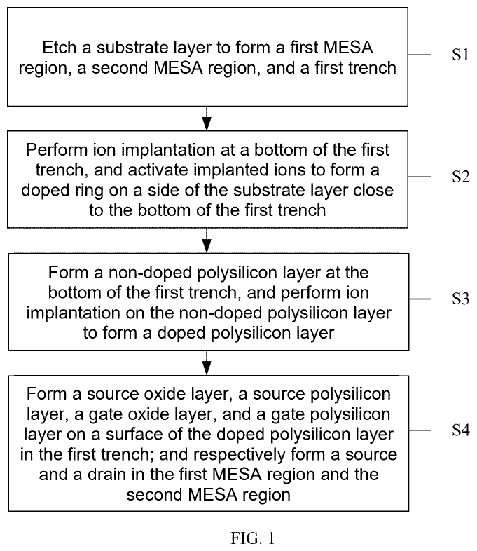

With reference to FIG. 1, FIG. 1 is a flowchart of a method for fabricating a power semiconductor device provided by the present application. The fabrication method includes the following steps:
S1: Etch a substrate layer to form a first MESA region, a second MESA region, and a first trench.
S2: Perform ion implantation at a bottom of the first trench, and activate implanted ions to form a doped ring on a side of the substrate layer close to the bottom of the first trench.
S3: Form a non-doped polysilicon layer at the bottom of the first trench, and perform ion implantation on the non-doped polysilicon layer to form a doped polysilicon layer.
S4: Form a source oxide layer, a source polysilicon layer, a gate oxide layer, and a gate polysilicon layer on a surface of the doped polysilicon layer in the first trench; and respectively form a source and a drain in the first MESA region and the second MESA region.

In some exemplary embodiments, a doped ring is formed by ion implantation at the bottom of the first trench, and a non-doped polysilicon layer is deposited in the first trench. Ion implantation is then performed on the non-doped polysilicon layer to form a doped polysilicon layer. Since the oxidation rate of doped polysilicon is higher than that of monocrystalline silicon, the present application utilizes the synergistic effect of the doped ring and the doped polysilicon layer at the bottom of the first trench to increase the oxidation rate at the bottom of the first trench, thereby increasing the thickness of the oxide layer at the bottom of the first trench. In addition, the doped polysilicon layer serves as a buffer layer covering the bottom of the first trench, filling in microscopic unevenness at the bottom of the first trench and reducing inconsistencies in oxidation rates at different locations caused by surface morphology differences during deposition. Furthermore, a certain amount of stress is introduced during the deposition and ion implantation processes of the polysilicon layer, which affects the lattice structure at the bottom of the first trench, alters the atomic spacing and chemical bond energy of different crystal planes, making the reactivity of different crystal planes in the oxidation process more similar, and reduces the oxidation rate difference at different locations. This optimizes the uniformity of the oxide layer thickness deposited at the bottom of the first trench, solves the problem of a thinner oxide layer at the bottom and corners of the first trench, thereby improving the insulation performance of the device and effectively avoiding the problem of device low-voltage breakdown caused by a locally over-thin oxide layer.

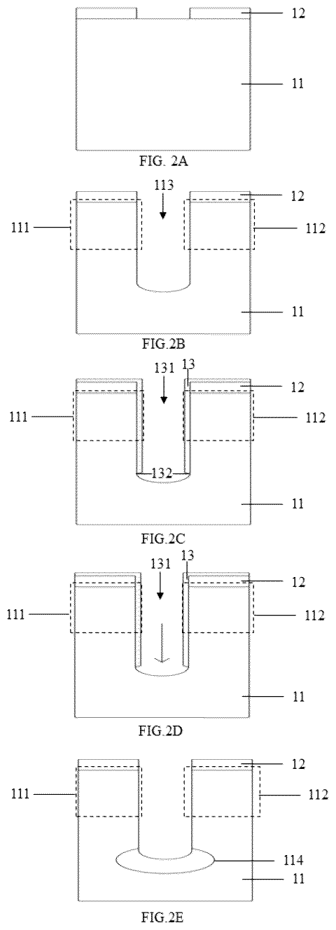

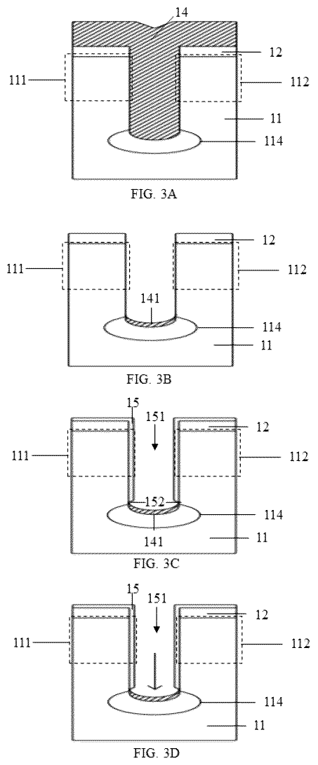

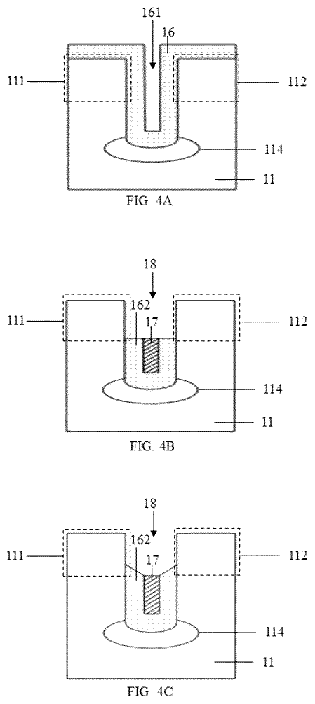

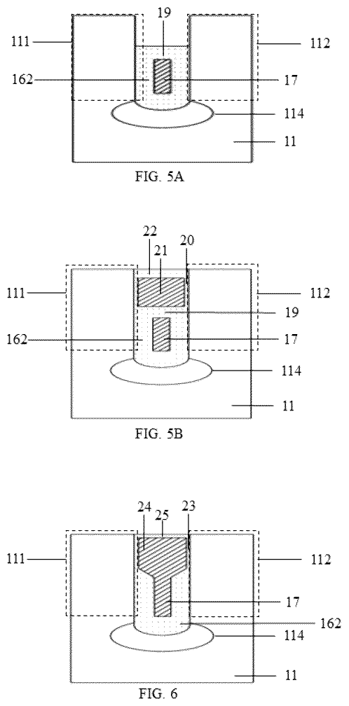

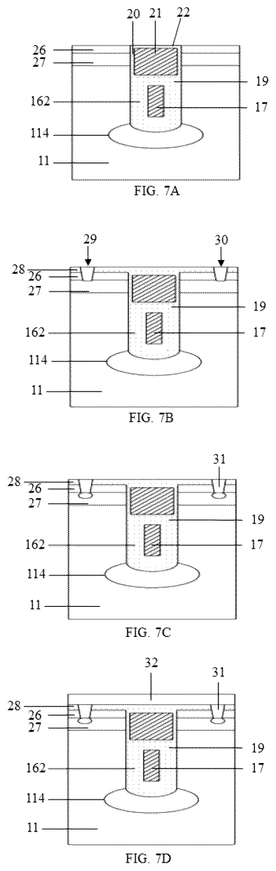

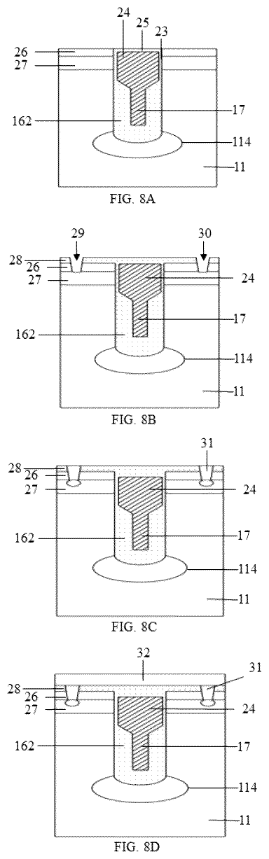

Specifically, the present application also provides another method for fabricating a power semiconductor device to further explain the above-mentioned method for fabricating a power semiconductor device, as shown in FIG. 2A to FIG. 8D. FIG. 2A to FIG. 2E illustrate a process of forming a doping ring according to the present disclosure. FIG. 3A to FIG. 3D illustrate a process of forming a non-doped polysilicon layer according to the present disclosure. FIG. 4A to FIG. 4C illustrate a process of forming a source polysilicon and an oxide layer according to the present disclosure. FIG. 5A to FIG. 5B illustrate a process of forming a first type of gate polysilicon and an oxide layer according to the present disclosure. FIG. 6 is a flowchart of a process of forming a gate polysilicon and an oxide layer according to the present disclosure. FIG. 7A to FIG. 7D illustrate a process of forming a source and a drain according to the present disclosure. FIG. 8A to FIG. 8D illustrate a process of forming a source and a drain according to the present disclosure.
S100: Provide a substrate layer 11, and grow a hard mask 12 on a surface of the substrate layer 11, as shown in FIG. 2A.
S101: Etch the substrate layer 11 to form a first MESA region 111, a second MESA region 112, and a first trench 113, as shown in FIG. 2B.

Moreover, the depth of the first groove 113 is 2 μm to 10 μm. For example, the depth of the first groove 113 can be 2 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, or 10 μm.
S102: Deposit a first ion implantation barrier layer 13 on a sidewall and a bottom of the first groove 113; the first ion implantation barrier layer 13 has a second groove 131.
S103: Etch the first ion implantation barrier layer 13 at a bottom of the second groove 131 to form a first ion implantation window 132, as shown in FIG. 2C.

In some exemplary embodiments, the first ion implantation barrier layer 13 is silicon nitride (Si₃N₄).
S104: Implant a donor impurity or an acceptor impurity into the bottom of the first groove 113 based on the first ion implantation window 132, as shown in FIG. 2D, and etch to remove the first ion implantation barrier layer 13 on a sidewall of the second groove 131.

The energy range for ion implantation into the first groove 113 is 20 KeV to 1 MeV, the dose range is 1×10¹² to 1×10¹³, and the number of implantations is 1 to 3 times. For example, the ion implantation energy can be 20 KeV, 200 KeV, 400 KeV, 600 KeV, 800 KeV, or 1 MeV; the ion implantation dose can be 1×10¹², 5×10¹², or 1×10¹³; and the number of implantations can be 1, 2, or 3 times.
S105: Activate the donor impurity or acceptor impurity to form a doped ring 114 on a side of the substrate layer 11 close to the bottom of the first groove 113, as shown in FIG. 2E.

Specifically, in some embodiments of the present application, rapid thermal annealing (RTA) or a furnace can be used to perform activation treatment of the implanted ions.
S106: Deposit undoped polysilicon 14 in the first groove 113, as shown in FIG. 3A, and etch a portion of the undoped polysilicon 14 to form an undoped polysilicon layer 141 at the bottom of the first groove 113, as shown in FIG. 3B.

Furthermore, the thickness of the undoped polysilicon layer 141 is 100 Å to 2000 Å. For example, the thickness of the undoped polysilicon layer 141 can be 100 Å, 300 Å, 500 Å, 700 Å, 900 Å, 1100 Å, or 2000 Å.
S107: Deposit a second ion implantation barrier layer 15 on the sidewall of the first groove 113 and on a surface of the undoped polysilicon layer 141; the second ion implantation barrier layer 15 has a third groove 151.

In a specific example of the present application, the second ion implantation barrier layer 15 is silicon nitride (Si₃N₄).
S108: Etch the second ion implantation barrier layer 15 on the surface of the undoped polysilicon layer 141 to form a second ion implantation window 152, as shown in FIG. 3C.
S109: Implant a donor impurity or an acceptor impurity into the undoped polysilicon layer 141 based on the second ion implantation window 152 to form a doped polysilicon layer 142, as shown in FIG. 3D, and then etch to remove the second ion implantation barrier layer 15 on the sidewall of the third groove 151.

The energy range for ion implantation into the undoped polysilicon layer 141 is 20 KeV to 1 MeV, the dose range is 1×10¹⁴ to 1×10²⁰, and the number of implantations is 1 to 3 times. For example, the ion implantation energy can be 20 KeV, 200 KeV, 400 KeV, 600 KeV, 800 KeV, or 1 MeV; the ion implantation dose can be 1×10¹⁴, 1×10¹⁵, 1×10¹⁶, 1×10¹⁷, 1×10¹⁸, 1×10¹⁹, or 1×10²⁰; and the number of implantations can be 1, 2, or 3 times.
S110: Grow a field oxide layer 16 at a high temperature on the sidewall of the first groove 113 and the surface of the doped polysilicon layer 142; the field oxide layer 16 has a fourth groove 161, as shown in FIG. 4A.

Specifically, since the bottom of the first groove 113 has the doped ring 114 and the doped polysilicon layer 142, the oxidation rate at the bottom of the first groove can be increased, thereby achieving an increase in the thickness of the field oxide layer 16.
S111: Deposit a polysilicon layer in the fourth groove 161, and perform etch back on the field oxide layer 16 on the sidewall of the fourth groove 161 and the polysilicon layer in the fourth groove 161 to form a source oxide layer 162, a source polysilicon layer 17, and a fifth groove 18 located on the surfaces of the source oxide layer 162 and the source polysilicon layer 17.

In some exemplary embodiments, an upper surface of the source oxide layer 162 is flush with an upper surface of the source polysilicon layer 17, as shown in FIG. 4B. In some exemplary embodiments, the upper surface of the source oxide layer 162 close to the sidewall of the first groove 113 is higher than the upper surface of the source polysilicon layer 17, as shown in FIG. 4C.
S112: Form a gate oxide layer and a gate polysilicon layer in the fifth groove 18.

In some exemplary embodiments, due to the different shapes of the source oxide layer 162 and the source polysilicon layer 17, step S112 may be implemented by two different methods.
Method 1: Form an isolation oxide layer 19 at the bottom of the fifth groove 18, as shown in FIG. 5A, and form a first gate oxide layer 20 on a sidewall of the fifth groove 18; the first gate oxide layer 20 has a sixth groove. Deposit a first gate polysilicon layer 21 in the sixth groove; an upper surface of the first gate polysilicon layer 21 is lower than upper surfaces of the first MESA region 111 and the second MESA region 112. Deposit a second gate oxide layer 22 on the surface of the first gate polysilicon layer 21, thereby forming a gate oxide layer and a gate polysilicon layer in the fifth groove 18, as shown in FIG. 5B.

The thickness of the isolation oxide layer 19 is 1000 Å to 10000 Å. For example, the thickness of the isolation oxide layer 19 can be 1000 Å, 2000 Å, 3000 Å, 4000 Å, 5000 Å, 6000 Å, 7000 Å, 8000 Å, 9000 Å, or 10000 Å.

The thicknesses of the first gate oxide layer 20 and the second gate oxide layer 22 are each in the range of 350 Å to 900 Å. For example, the thickness of the first gate oxide layer 20 and the second gate oxide layer 22 can be 350 Å, 550 Å, 750 Å, or 900 Å.

The thickness of the first gate polysilicon layer 21 is 500 Å to 1500 Å. For example, the thickness of the first gate polysilicon layer 21 can be 500 Å, 1000 Å, or 1500 Å.

Method 2: Form a third gate oxide layer 23 on a sidewall of the fifth groove 18; the third gate oxide layer 23 has a seventh groove. Deposit a second gate polysilicon layer 24 in the seventh groove; an upper surface of the second gate polysilicon layer 24 is lower than upper surfaces of the first MESA region 111 and the second MESA region 112. Deposit a fourth gate oxide layer 25 on a surface of the second gate polysilicon layer 24, as shown in FIG. 6.

The thicknesses of the third gate oxide layer 23 and the fourth gate oxide layer 25 are each in the range of 350 Å to 900 Å. For example, the thickness of the third gate oxide layer 23 and the fourth gate oxide layer 25 can be 350 Å, 550 Å, 750 Å, or 900 Å.

The thickness of the second gate polysilicon layer 24 is 500 Å to 1500 Å. For example, the thickness of the second gate polysilicon layer 24 can be 500 Å, 1000 Å, or 1500 Å.
S113: Perform ion implantation and drive-in for the first MESA region 111 and the second MESA region 112, respectively, to form a body region 26 and a source region 27, as shown in FIG. 7A and FIG. 8A.
S114: Deposit an oxide layer 28 on surfaces of the first MESA region 111, the second MESA region 112, and the gate oxide layer, and etch the oxide layer 28 on the surfaces of the body region 26, the source region 27, the first MESA region 111, and the second MESA region 112 to form a first contact hole 29 and a second contact hole 30, as shown in FIG. 7B and FIG. 8B.
S115: Perform ion implantation, annealing, and activation at bottoms of the first contact hole 29 and the second contact hole 30, and fill the first contact hole 29 and the second contact hole 30 with tungsten plugs 31, as shown in FIG. 7C and FIG. 8C.
S116: Deposit a metal layer 32 on surfaces of the oxide layer 28 and the tungsten plugs 31, to form a power semiconductor device, as shown in FIG. 7D and FIG. 8D.

Based on the power semiconductor device manufacturing method provided in the above exemplary embodiments, the present application further provides a power semiconductor device, which can be obtained by the aforementioned power semiconductor device manufacturing method.

In some exemplary embodiments, the power semiconductor device herein includes, but is not limited to, Metal-Oxide-Semiconductor Field-Effect Transistor (MOSFET), which is a type of transistor to amplify or switch electronic signals. It controls the flow of current between the source and drain terminals by applying a voltage to the gate terminal, which modulates the conductivity of a semiconductor channel. In some exemplary embodiments, the power semiconductor device can be an enhancement-mode MOSFET, a depletion-mode MOSFET, an N-channel MOSFET, or a P-channel MOSFET. MOSFETs are favored for their high efficiency, low power consumption, and ability to handle high voltages and currents in compact designs.

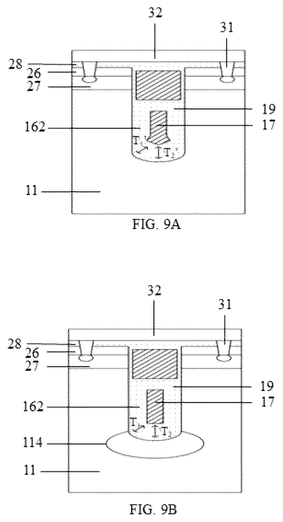

As shown in FIGS. 9A and 9B, which is a schematic structural diagram of a conventional power semiconductor device and the power semiconductor device provided in the present application, FIG. 9A is the schematic structural diagram of the conventional power semiconductor device. FIG. 9B is the schematic structural diagram of the power semiconductor device provided in the present application.

The power semiconductor device manufacturing method provided in the embodiments of the present application forms a doped ring by injecting donor impurities or acceptor impurities at different angles and in different doses at the bottom of the groove. Meanwhile, an undoped polysilicon layer is deposited at the bottom of the groove, and donor impurities or acceptor impurities are injected into the undoped polysilicon layer in different doses. By utilizing the synergistic effect of both, the problem of a thinner deposition layer at the bottom and corners of the groove (T1′<T1, T2′<T2) caused by the difference in specific growth rates of different crystal planes (100)/(110)/(111) at the bottom of the groove is solved, thereby addressing the issues of low breakdown voltage and limitations in the reduction of cell size. This effectively alleviates the problem of poor uniformity in deposition layer thickness during chemical vapor deposition.

Moreover, by combining the doped polysilicon layer and the groove bottom with the injection of donor or acceptor impurities, it is possible to achieve mutual tuning of Miller capacitance, specific on-resistance, and breakdown voltage. For example, when N-type impurity-doped bulk silicon is used as the epitaxial layer, P-type impurities are injected at the groove bottom, and low-dose N-type impurities are injected into the undoped polysilicon layer, the Miller capacitance of the device can be reduced by 14.7%, while the breakdown voltage of the device can be increased by 9.4%. When high-dose N-type impurities are injected into the undoped polysilicon layer, the specific on-resistance of the device can be reduced by 5.6%. When low-dose P-type impurities are injected into the undoped polysilicon layer, the Miller capacitance of the device can be reduced by 36.8%, while the breakdown voltage of the device can be increased by 8.8%. When high-dose P-type impurities are injected into the undoped polysilicon layer, the Miller capacitance of the device can be reduced by 67.6%, while the breakdown voltage of the device can be increased by 9.7%. Device performance tuning can be achieved solely through ion implantation processes, which provides better performance tuning effects compared to layout involvement or changes in device structure. It is worth noting that the power semiconductor device manufacturing method provided in the present application is applicable to silicon-based/silicon carbide-based trench power devices.

Obviously, the above embodiments are merely provided as examples for illustrating the present invention and are not intended to limit the present invention. For a person skilled in the art, various other modifications or alterations in different forms can be made based on the above description. It is neither necessary nor possible to exhaust all the embodiments herein. Any obvious modifications or alterations derived therefrom shall still fall within the protection scope of the present invention.

What is claimed is

1. A method for fabricating a power semiconductor device, comprising:
etching a substrate layer to form a first MESA region, a second MESA region, and a first trench;
performing ion implantation at a bottom of the first trench, and activating implanted ions to form a doped ring in the substrate layer close to the bottom of the first trench;
forming an undoped polysilicon layer at the bottom of the first trench, and performing ion implantation on the undoped polysilicon layer to form a doped polysilicon layer;
forming a source oxide layer, a source polysilicon layer, a gate oxide layer, and a gate polysilicon layer on a surface of the doped polysilicon layer in the first trench; and
forming a source and a drain respectively in the first MESA region and the second MESA region.

2. The method for fabricating a power semiconductor device according to claim 1, wherein the performing of the ion implantation at the bottom of the first trench and activating implanted ions to form the doped ring in the substrate layer close to the bottom of the first trench comprise:
depositing a first ion implantation barrier layer on a sidewall and the bottom of the first trench, wherein the first ion implantation barrier layer has a second trench;
etching the first ion implantation barrier layer at a bottom of the second trench to form a first ion implantation window;
injecting a donor impurity or acceptor impurity into the bottom of the first trench based on the first ion implantation window, and etching to remove the first ion implantation barrier layer on a sidewall of the second trench; and
activating the donor impurity or acceptor impurity to form a doped ring in the substrate layer close to the bottom of the first trench.

3. The method for fabricating a power semiconductor device according to claim 1, wherein the forming of the undoped polysilicon layer at the bottom of the first trench and performing ion implantation on the undoped polysilicon layer to form the doped polysilicon layer comprise:
depositing non-doped polysilicon in the first trench, etching part of the non-doped polysilicon to form the non-doped polysilicon layer at the bottom of the first trench;
depositing a second ion implantation blocking layer on a sidewall of the first trench and a surface of the non-doped polysilicon layer, wherein the second ion implantation blocking layer has a third trench;
etching the second ion implantation blocking layer on the surface of the non-doped polysilicon layer to form a second ion implantation window; and
injecting a donor impurity or acceptor impurity into the non-doped polysilicon layer based on the second ion implantation window to form the doped polysilicon layer, and etching to remove the second ion implantation blocking layer on a sidewall of the third trench.

4. The method for fabricating a power semiconductor device according to claim 1, wherein the forming of the source oxide layer, the source polysilicon layer, the gate oxide layer, and the gate polysilicon layer on the surface of the doped polysilicon layer in the first trench comprises:
growing a field oxide layer at a high temperature on a sidewall of the first trench and a surface of the doped polysilicon layer, wherein the field oxide layer has a fourth trench;
depositing a polysilicon layer in the fourth trench, and etching back the field oxide layer on a sidewall of the fourth trench and the polysilicon layer in the fourth trench to form the source oxide layer, the source polysilicon layer, and a fifth trench located on surfaces of the source oxide layer and the source polysilicon layer; and
forming the gate oxide layer and the gate polysilicon layer in the fifth trench.

5. The method for fabricating a power semiconductor device according to claim 4, wherein when an upper surface of the source oxide layer is flush with an upper surface of the source polysilicon layer, the forming of the gate oxide layer and the gate polysilicon layer in the fifth trench comprises:
forming an isolation oxide layer at a bottom of the fifth trench and forming a first gate oxide layer on a sidewall of the fifth trench, wherein the first gate oxide layer has a sixth trench;
depositing a first gate polysilicon layer in the sixth trench, wherein an upper surface of the first gate polysilicon layer is lower than upper surfaces of the first MESA region and the second MESA region; and
depositing a second gate oxide layer on a surface of the first gate polysilicon layer.

6. The method for fabricating a power semiconductor device according to claim 4, wherein when an upper surface of the source oxide layer close to the sidewall of the first trench is higher than an upper surface of the source polysilicon layer, the forming of the gate oxide layer and the gate polysilicon layer in the fifth trench comprises:
forming a third gate oxide layer on a sidewall of the fifth trench, wherein the third gate oxide layer has a seventh trench;
depositing a second gate polysilicon layer in the seventh trench, wherein an upper surface of the second gate polysilicon layer is lower than upper surfaces of the first MESA region and the second MESA region; and
depositing a fourth gate oxide layer on a surface of the second gate polysilicon layer.

7. The method for fabricating a power semiconductor device according to claim 1, wherein the method has at least one of the following features:
a depth of the first trench is 2 μm to 10 μm;
a thickness of the non-doped polysilicon layer is 100 Å to 2000 Å;
for the ion implantation at the bottom of the first trench, an energy range is 20 KeV to 1 MeV, a doze range is 1×10¹² to 1×10¹³, and a number of implantations is 13 times; or
for the ion implantation into the non-doped polysilicon layer, an energy range is 20 KeV to 1 MeV, a doze range is 1×10^{14 to} 1×10²⁰, and a number of implantations is 13 times.

8. The method for fabricating a power semiconductor device according to claim 5, wherein
a thickness of the isolation oxide layer is 1000 Å to 10000 Å;
thicknesses of the first gate oxide layer and the second gate oxide layer are each 350 Å to 900 Å; and
a thickness of the first gate polysilicon layer is 500 Å to 1500 Å.

9. The method for fabricating a power semiconductor device according to claim 6, wherein
thicknesses of the third gate oxide layer and the fourth gate oxide layer are each 350 Å to 900 Å; and
a thickness of the second gate polysilicon layer is 500 Å to 1500 Å.

10. The method for fabricating a power semiconductor device according to claim 1, wherein the power semiconductor device comprises a Metal-Oxide-Semiconductor Field-Effect Transistor (MOSFET).

11. A power semiconductor device, wherein the power semiconductor device is fabricated by a method comprising the following steps:
etching a substrate layer to form a first MESA region, a second MESA region, and a first trench;
performing ion implantation at a bottom of the first trench, and activating implanted ions to form a doped ring in the substrate layer close to the bottom of the first trench;
forming an undoped polysilicon layer at the bottom of the first trench, and performing ion implantation on the undoped polysilicon layer to form a doped polysilicon layer;
forming a source oxide layer, a source polysilicon layer, a gate oxide layer, and a gate polysilicon layer on a surface of the doped polysilicon layer in the first trench; and
forming a source and a drain respectively in the first MESA region and the second MESA region.

12. The power semiconductor device according to claim 11, wherein the performing of the ion implantation at the bottom of the first trench and activating implanted ions to form the doped ring in the substrate layer close to the bottom of the first trench comprise:
depositing a first ion implantation barrier layer on a sidewall and the bottom of the first trench, wherein the first ion implantation barrier layer has a second trench;
etching the first ion implantation barrier layer at a bottom of the second trench to form a first ion implantation window;
injecting a donor impurity or acceptor impurity into the bottom of the first trench based on the first ion implantation window, and etching to remove the first ion implantation barrier layer on a sidewall of the second trench; and
activating the donor impurity or acceptor impurity to form a doped ring in the substrate layer close to the bottom of the first trench.

13. The power semiconductor device according to claim 11, wherein the forming of the undoped polysilicon layer at the bottom of the first trench and performing ion implantation on the undoped polysilicon layer to form the doped polysilicon layer comprise:
depositing non-doped polysilicon in the first trench, etching part of the non-doped polysilicon to form the non-doped polysilicon layer at the bottom of the first trench;
depositing a second ion implantation blocking layer on a sidewall of the first trench and a surface of the non-doped polysilicon layer, wherein the second ion implantation blocking layer has a third trench;
etching the second ion implantation blocking layer on the surface of the non-doped polysilicon layer to form a second ion implantation window; and
injecting a donor impurity or acceptor impurity into the non-doped polysilicon layer based on the second ion implantation window to form the doped polysilicon layer, and etching to remove the second ion implantation blocking layer on a sidewall of the third trench.

14. The power semiconductor device according to claim 11, wherein the forming of the source oxide layer, the source polysilicon layer, the gate oxide layer, and the gate polysilicon layer on the surface of the doped polysilicon layer in the first trench comprises:
growing a field oxide layer at a high temperature on a sidewall of the first trench and a surface of the doped polysilicon layer, wherein the field oxide layer has a fourth trench;
depositing a polysilicon layer in the fourth trench, and etching back the field oxide layer on a sidewall of the fourth trench and the polysilicon layer in the fourth trench to form the source oxide layer, the source polysilicon layer, and a fifth trench located on surfaces of the source oxide layer and the source polysilicon layer; and
forming the gate oxide layer and the gate polysilicon layer in the fifth trench.

15. The power semiconductor device according to claim 14, wherein when an upper surface of the source oxide layer is flush with an upper surface of the source polysilicon layer, the forming of the gate oxide layer and the gate polysilicon layer in the fifth trench comprises:
forming an isolation oxide layer at a bottom of the fifth trench and forming a first gate oxide layer on a sidewall of the fifth trench, wherein the first gate oxide layer has a sixth trench;
depositing a first gate polysilicon layer in the sixth trench, wherein an upper surface of the first gate polysilicon layer is lower than upper surfaces of the first MESA region and the second MESA region; and
depositing a second gate oxide layer on a surface of the first gate polysilicon layer.

16. The power semiconductor device according to claim 14, wherein when an upper surface of the source oxide layer close to the sidewall of the first trench is higher than an upper surface of the source polysilicon layer, the forming of the gate oxide layer and the gate polysilicon layer in the fifth trench comprises:
forming a third gate oxide layer on a sidewall of the fifth trench, wherein the third gate oxide layer has a seventh trench;
depositing a second gate polysilicon layer in the seventh trench, wherein an upper surface of the second gate polysilicon layer is lower than upper surfaces of the first MESA region and the second MESA region; and
depositing a fourth gate oxide layer on a surface of the second gate polysilicon layer.

17. The power semiconductor device according to claim 11, wherein the power semiconductor device has at least one of the following features:
a depth of the first trench is 2 μm to 10 μm;
a thickness of the non-doped polysilicon layer is 100 Å to 2000 Å;
for the ion implantation at the bottom of the first trench, an energy range is 20 KeV to 1 MeV, a doze range is 1×10¹² to 1×10^{13,} and a number of implantations is 13 times; or
for the ion implantation into the non-doped polysilicon layer, an energy range is 20 KeV to 1 MeV, a doze range is 1×10¹⁴ to 1×10²⁰, and a number of implantations is 13 times.

18. The power semiconductor device according to claim 15, wherein
a thickness of the isolation oxide layer is 1000 Å to 10000 Å;
thicknesses of the first gate oxide layer and the second gate oxide layer are each 350 Å to 900 Å; and
a thickness of the first gate polysilicon layer is 500 Å to 1500 Å.

19. The power semiconductor device according to claim 16, wherein
thicknesses of the third gate oxide layer and the fourth gate oxide layer are each 350 Å to 900 Å; and
a thickness of the second gate polysilicon layer is 500 Å to 1500 Å.

20. The power semiconductor device according to claim 11, wherein the power semiconductor device comprises a Metal-Oxide-Semiconductor Field-Effect Transistor (MOSFET).
